(19) United States
(12) Patent Application Publication
(10) Pub. No.: US 2012/0137187 A1
(43) Pub. Date: May 31, 2012

(54) SYSTEM AND METHOD FOR SCAN TESTING INTEGRATED CIRCUITS

(75) Inventors: Sandeep Jain, Rewari (IN); Abhishek Chaudhary, Nagpur (IN); Supreet Jeloka, Bangalore (IN)

(73) Assignee: FREESCALE SEMICONDUCTOR, INC, Austin, TX (US)

(21) Appl. No.: 12/954,907

(22) Filed: Nov. 28, 2010

(51) Int. Cl. G01R 31/3177; G06F 11/25

(52) U.S. Cl. 714/731; 714/E11.155

(57) ABSTRACT

A system for scan testing an IC includes one or more scan registers, one or more scan-in pads, one or more scan-out pads, and one or more comparators. Scan test data is transmitted from the scan-in pads to the scan registers. The functional response obtained from the scan test is transmitted to the comparator. The scan-out pad transmits the expected data to the comparator. The comparator compares the expected data and the functional response data and the comparison result is stored. The test result data is transmitted at positive and negative edges of the test clock signal.

### BACKGROUND OF THE INVENTION

The present invention relates generally to testing of integrated circuits (IC), and more specifically, to a system and method for performing a scan test on an IC.

Recent years have seen a tremendous advancement in the field of VLSI and multi-layered PCB. Integrated circuits (ICs) that contained a few hundred transistors a few decades ago, now include millions of transistors. This has led to considerable miniaturization of electronic circuits, thereby increasing the circuit density. Multi-layered PCBs that have the capability to hold electronic components on both sides of the PCB have further contributed to miniaturization of electronic circuits. However, miniaturization has made circuit testing difficult. Traditional testing techniques, such as ‘bed of nails’ testing, do not yield accurate test results and are expensive. Such test methodologies fail when used to test multi-layered PCBs, pitched packages, and double-sided surface mount boards.

In light of the above-stated limitations of traditional testing techniques, scan testing was developed. FIG. 1 is a general block diagram illustrating a scan register configuration of an IC 100. The IC 100 includes a scan-in pad 102, a scan register 104, and a scan-out pad 106. The scan register 104 includes one or more scan cells, such as a scan cell 108. The IC 100 also includes digital logic 110.

The scan-in pad 102 and the scan-out pad 106 are coupled to pins of the IC 100 that are in the vicinity of the two pads (scan-in and scan-out). The scan-in and scan-out pads 102 and 106 also are connected to the scan cells 108. Multiple scan cells together form the scan register 104. Further, the scan cells are connected to the digital logic 110. The IC 100 also has a TCLK port (not shown) to provide a test clock signal to the IC 100.

Test data is input to the IC 100 via the scan-in pad 102. The test data may be a test pattern generated by an ATPG (automatic test pattern generator) to perform a scan test on the IC 100. The test data is transmitted from the scan-in pad 102 to an adjoining scan cell and then it ripples through the scan cells until all the scan cells are loaded with test data in synchronization with the pulses of the test clock signal. This process of shifting the test data into the various scan cells is known as the shift-in operation. Thereafter, at the last test clock pulse belonging to the shift-in phase of the scan, the scan test data in the scan cells is applied to the digital logic 110. Thereafter, a capture phase of the scan test is initiated in which the functional responses of the digital logic 110 to the scanned-in test data are captured in the scan cells. Subsequently, a shift-out phase is initiated, which involves shifting the test response data from the scan cells to the scan-out pins of the IC 100, and to an external tester (not shown). The external tester compares the test response data with expected “good-device” response data to differentiate between an error-free device and a faulty device.

FIG. 2 is a timing diagram 200 for the scan testing of the IC 100 (FIG. 1). A test clock signal is provided to the IC 100 at the TCLK port and the scan testing is executed as described above based on the pulses of the test clock signal. At time instant t₁, first test data, scan-in_1, is transmitted to the scan-in pad 102. Simultaneously, test response data, scan-out_1 (from a previous scan test cycle), present in the scan cells is shifted-out from the scan-out pad 106. This procedure is repeated at time instants t₂ and t₃ until the scan test is completed.

As described above, the scan testing includes transmitting the test data to the scan-in pads, transmitting the data from the scan-in pads to the scan cells, transmitting the test data and the test response data through the scan chain, transmitting the test response data from the scan cells to the scan-out pad, and transmitting the test response data from the scan-out pad to the external tester. Thus, a considerable portion of the test time consumed may be attributed to transmitting of data to the scan-in pad, between the scan-in pad, scans cells and scan-out pad, and from the scan-out pad to the external tester and the time consumed transmitting data between the scan cells is negligible. Further, the time consumed transmitting data from the scan-out pad to the external tester is greater than the time spent transmitting the data to the scan-in pads from the ATPG. Considering that scan-in pads, scan-out pads and scan cells operate in synchronization, the data transmission rate at each level is set to the slowest transmission rate, which is the transmission rate of the scan-out pads. As the result, the overall throughput of the system is affected due to the slow response of the scan-out pads.

It would be advantageous to be able to decrease test time by improving upon the above-described scan testing limitations.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic diagram of a conventional IC that includes scan test logic;

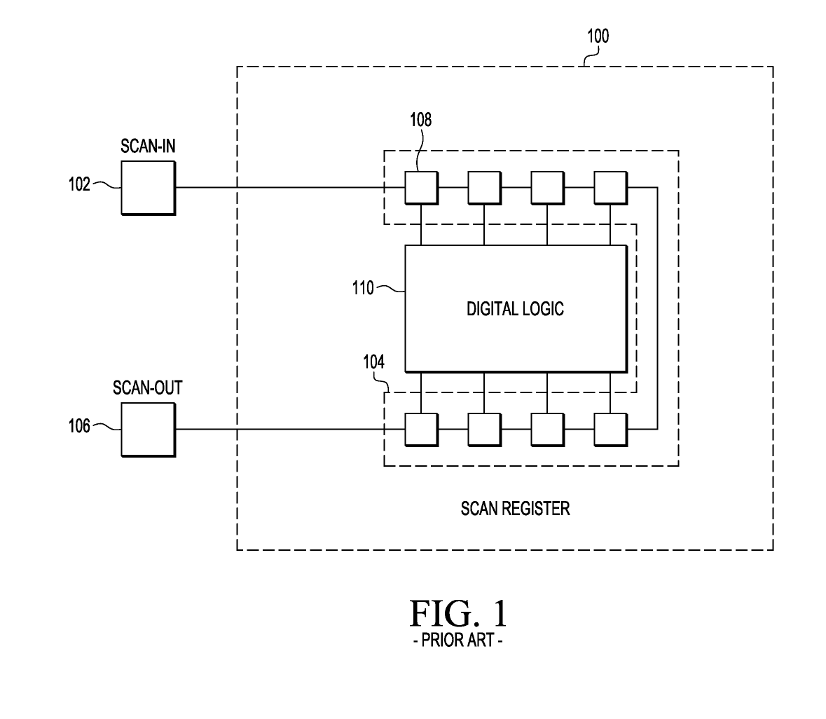

FIG. 2 is a timing diagram for scan testing the IC of FIG. 1;

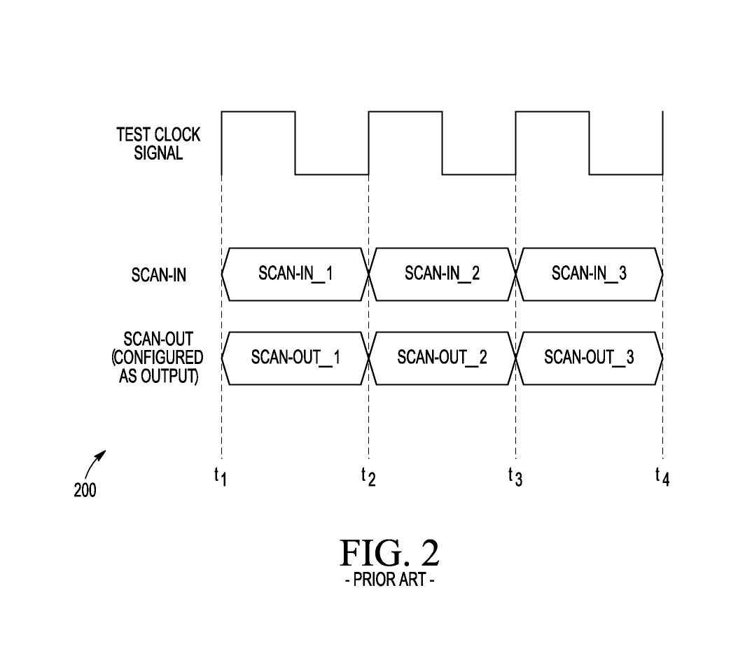

FIG. 3 is a schematic diagram of an IC illustrating a scan test system in accordance with an embodiment of the present invention;

FIG. 4 is a schematic diagram of a comparator in accordance with an embodiment of the present invention;

FIG. 5 is a timing diagram illustrating the timing for scan testing in accordance with an embodiment of the present invention; and

FIG. 6 is a flowchart illustrating a method for testing an IC in accordance with an embodiment of the present invention.

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of present invention, a system for testing an integrated circuit is provided. The system includes one or more scan-in pads connected to one or more scan cells. The one or more scan cells are configured as a shift register. The shift register so formed is known as scan register. Further, one or more scan-out pads are connected to the one or more scan cells. Further, one or more comparators are connected to the one or more scan-out pads and one or more scan registers in the IC. Scan test data is transmitted from the one or more scan-in pads to the one or more scan cells. The scan test data is traversed along the one or more scan registers. Further, the scan test data is transmitted to the digital logic of the integrated circuit. The scan test data is processed by the digital logic of the integrated circuit to generate functional response data that is transmitted back to the one or more scan registers. The one or more scan-out pads are also configured as scan-in pads to the IC to provide expected data to the comparator. The functional response data from the one or more scan registers and the expected data from the one or more scan-out pads is compared in the one or more comparators. The one or more comparators store the outcome of the scan test as a result bit.

In another embodiment of the present invention, a method for scan testing an IC is provided. Scan test data is transmitted from the one or more scan-in pads to the one or more scan registers based on the test clock signal. The one or more scan registers pass the scan test data to an internal logic of the integrated circuit. The test data is processed by the digital logic to generate functional response data. The functional response data from the digital logic of the integrated circuit is transmitted to the one or more scan registers. One or more scan-out pads are configured to provide expected data and mask signal to the integrated circuit based on the test clock signal. The mask signal obscures the functional response data received from the one or more scan register. The expected data from the one or more scan-out pads and the functional response data from the one or more scan registers are compared in the one or more comparators.

Various embodiments of the present invention provide a system and method for testing integrated circuits. The system includes one or more scan-in pads. The one or more scan-in pads transmit scan test data to one or more scan cells. The scan test data is then transmitted to the internal logic. The scan test data is processed by the internal logic of the integrated circuit to generate functional response data. Further, one or more scan-out pads are also configured as scan-in pads to transmit the expected IC response data and mask signals to the IC from the scan-out pads. In accordance with the invention, the scan-out pads do not accept the functional response data of the IC corresponding to the scan test data and thus do not transmit the functional response data outside of the IC for comparison with the expected data. Rather, the scan-out pads transmit the expected data to comparators inside the IC for comparison of the functional response data with the expected response data. The comparison results are transmitted either subsequent to each scan pattern cycle or when the scan test is complete. Thus, the scan-out pads function as scan-in pads during the major portion of the scan test. Further, the propagation delay of transmitting a signal from a scan-out pad to outside of the IC is greater than the propagation delay for transmitting a signal from outside of the IC to the scan-out pad. Thus, using the scan-out pads as scan-in pads considerably reduces the propagation delay.

Existing scan testing techniques involve transmitting the functional response data from the scan-out pad to the external tester. The time consumed in transmitting data from the scan-out pad to the external tester requires one test clock cycle. It is implemented by transmitting the functional response data from the scan-out pad to the external tester at the positive edge of the test clock. For synchronous operation, the scan-in pads, scan-out pads and scan cells also transmit data at the positive edge of the test clock signal. Since the present invention does not involve transmitting the functional response data outside of the IC, therefore it is not limited by the time consumed for transmitting data out of IC. As a result, the scan test data may be loaded from one or more scan-in pads at a positive edge as well as at a negative edge of the test clock signal. This leads to an increase in the throughput of the scan test process.

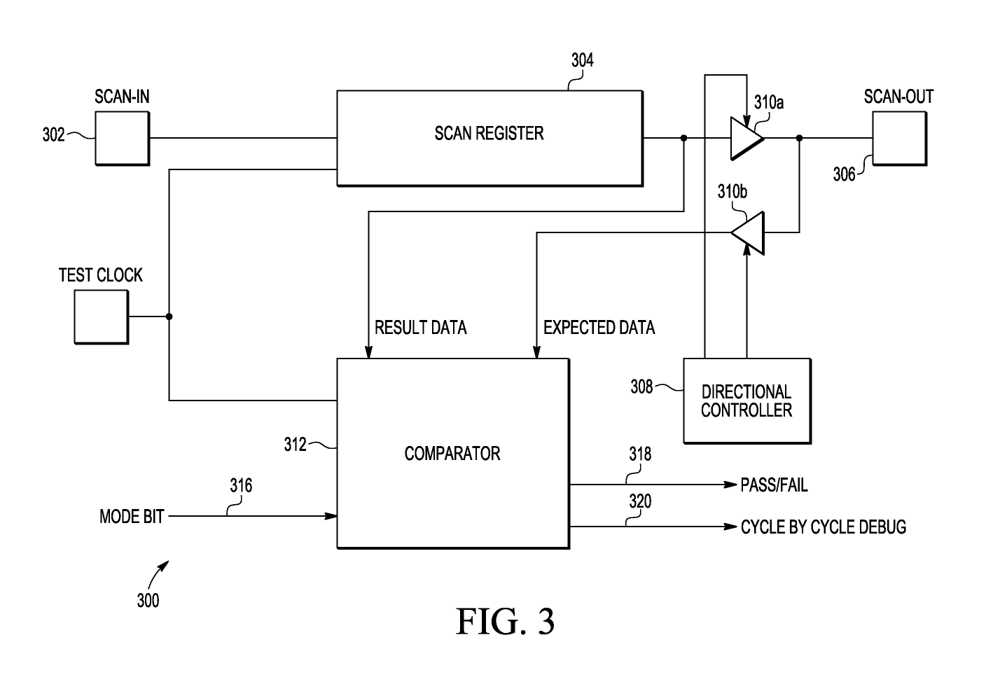

FIG. 3 illustrates a schematic block diagram of a system for scan testing in an IC 300 in accordance with an embodiment of the present invention. The system includes a scan-in pad 302, a scan register 304, a scan-out pad 306, a directional controller 308, tri-state buffers 310a, 310b, a comparator 312, a mode bit signal 316, a pass/fail signal 318, and a cycle-by-cycle debug signal 320.

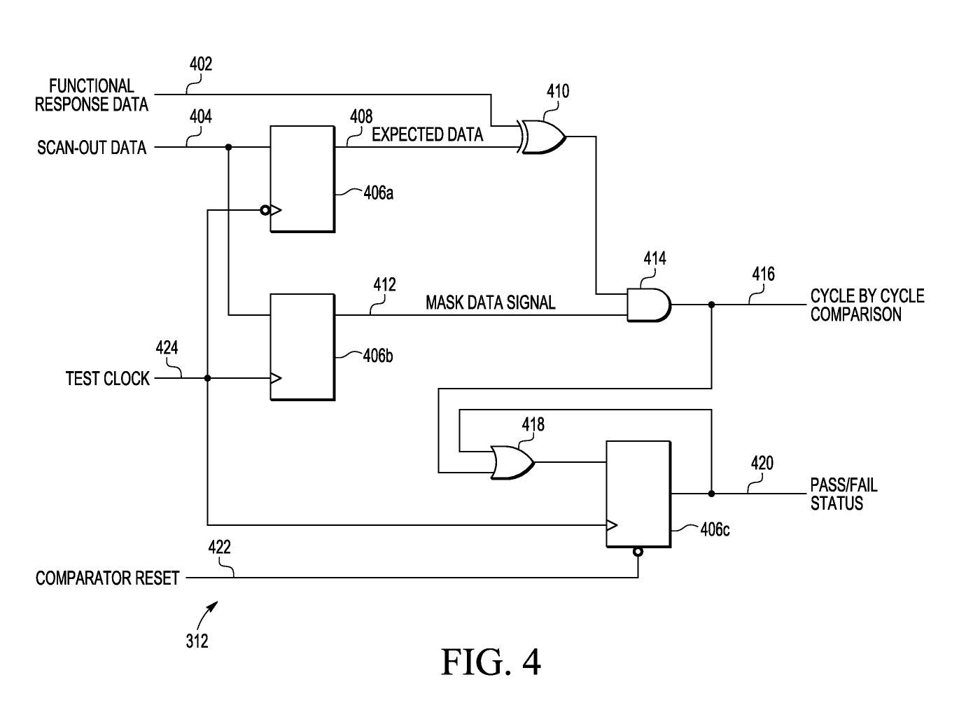

The scan-in pad 302 is connected to the scan register 304. The scan register 304 is further connected to the scan-out pad 306 and the comparator 312. Operation of the comparator 312 is controlled by the mode bit signal 316. The operation of the comparator 312 is explained in detail in conjunction with FIG. 4. The scan-out pad 306 is connected to the scan register 304. Further, the scan-out pad 306 is connected to the comparator 312. The directional controller 308 is connected to data channels that connect the scan-out pad 306 with the comparator 312 and the scan register 304, by the means of tri-state buffers 310a, 310b.

The scan testing of the IC 300 proceeds through a shift-in phase, a capture phase, and a shift-out phase and is controlled by the test clock signal (TCK) generated external to the IC 300. During the shift-in phase of scan testing, the scan-in pad 302 receives scan test data (scan-in data) from an external source such as an ATPG. Thereafter, the scan-in pad 302 transmits the scan test data to the scan register 304, thereby loading the various scan cells (not shown) of the scan register 304 with the scan test data. The scan test data is then applied to the digital logic (not shown) of the IC 300. The internal logic processes the scan test data and generates corresponding functional response data. Subsequently, the capture phase of the scan test is initiated in which the functional response data is captured at the corresponding scan cells. The functional response data is then shifted out from the scan register 304 to the comparator 312.

Additionally, the comparator 312 receives expected data from the scan-out pad 306. The transmission of data between the comparator 312 and the scan-out pad 306 is enabled by the directional controller 308. In an embodiment of the present invention, the directional controller 308 enables this data transmission by enabling the tri-state buffer 310b. Thus, the scan-out pad 306 that is conventionally used to transmit data outside of the IC is configured by the usage of directional controller 308 as a scan-in pad that is used for transmitting the expected data into the IC 300. The expected data represents the expected functional responses corresponding to the scan test data obtained from a flawless internal logic. Thus, to check whether the internal logic of the IC 300 is error free, the comparator 312 compares the functional response data with the expected data to generate a scan test status signal indicating the pass or fail status of the IC 300. Hereinafter, the scan test status signal will be referred to as a pass/fail status signal. The pass/fail status signal is generated when the scan test of the IC 300 is complete. This mode of operation of the comparator 312 is known as the halt debug mode. In an embodiment of the present invention, the comparator 312 operates in a monitor debug mode. During a monitor debug mode, the comparator 312 generates a pass/fail status signal subsequent to each test pattern cycle. In an embodiment of the present invention, the operational mode of the comparator 312 is switched between a halt debug mode and a monitor debug mode by a mode bit signal 316. The generation of the pass/fail status signal has been explained in detail in conjunction with FIG. 4.

Further, the comparator 312 also receives a mask signal from the scan-out pad 306. The mask signal prevents comparison of the functional response data with the expected data. It should be realized by persons skilled in the art that the functional response data includes various combinations which need not essentially be compared with expected data. The mask signal serves the purpose of signaling the comparator 312 whether or not to compare the functional response data with expected data. The scan-out pad 306 transmits the expected data at the negative edge of the test clock signal and the mask signal at the positive edge of the test clock signal. In an embodiment of the present invention, the expected data can be received on the positive edge of the test clock signal and the mask signal at the negative edge.

It should be realized by the person skilled in the art that the time consumed to transmit the scan test data from the outside of an integrated circuit to the scan-in pad of the integrated circuit is comparatively less than shifting-out the functional response data, obtained from the scan register, from the scan-out pad to a tester. Configuring scan-out pad as a scan-in pad to provide the expected data and the mask signal reduces the time that was being consumed by the scan-out pad to shift-out the functional response data. This enables shifting-in of the scan test data at both positive and negative edges of the test clock signal. Thus, increasing the frequency at which the scan test data is provided to the integrated circuit. Further, the on-chip comparator compares the expected data with the functional response data to generate a pass/fail status signal to test the functionality of the integrated circuit. The above mentioned configuration reduces the overall scan test time by increasing the scan throughput.

Referring to FIG. 4, a detailed schematic diagram of the comparator 312 is illustrated, in accordance with an embodiment of the present invention. The comparator 312 includes a functional response data signal 402, a scan-out data signal 404, flip-flops 406a, 406b, 406c, an expected data signal 408, an XOR gate 410, a mask data signal 412, an AND gate 414, a cycle by cycle comparison signal 416, an OR gate 418, a pass/fail status signal 420, a comparator reset signal 422, and a test clock signal 424.

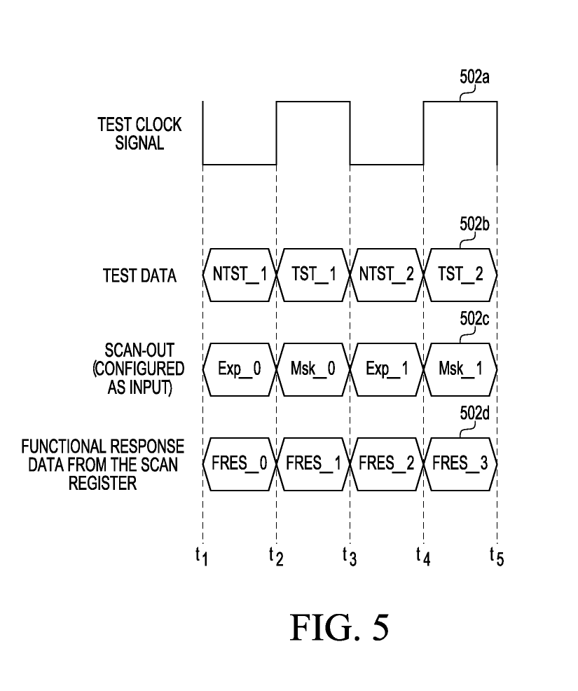

The functional response data signal 402 obtained from the scan register 304 (refer FIG. 3), is transmitted to the XOR gate 410. Further, the scan-out data signal 404 which contains the expected data, obtained from the scan-out pad 306 (refer FIG. 3), is transmitted to the input terminal of the flip-flops 406a and 406b. Further, the expected data signal 408, from the output terminal of the flip flop 406a, is transmitted to the XOR gate 410. Thereafter, the output signal generated by the XOR gate 410 is transmitted to the AND gate 414. Additionally, the mask data signal 412, obtained from the output terminal of the flip-flop 406b, is transmitted to the AND gate 414. Subsequently, the AND gate 414 performs a logical AND operation on the mask signal and the output signal of XOR gate 410 to generate a cycle-by-cycle comparison signal 416. The cycle-by-cycle comparison signal 416 is generated during the monitor debug mode. Further, output terminal of the AND gate 414 is connected to the OR gate 418. The cycle-by-cycle comparison signal 416 is transmitted to the OR gate 418. Further, the output of the OR gate 418 is connected to the input terminal of the flip-flop 406c. The output of the flip-flop 406c is the pass/fail status signal 420. The pass/fail status signal 420 is transmitted to the OR gate 418. The test clock signal 424 is transmitted to the flip-flops 406a, 406b, and 406c. The test clock signal 424 is inverted prior to the transmission to the flip-flop 406a. The operation of the comparator 312 is explained below in detail in conjunction with FIGS. 3 and 5.

Referring now to FIG. 5, a timing diagram for scan testing in accordance with an embodiment of present invention is shown. The timing diagram includes a waveform 502a corresponding to the test clock signal 424, a waveform 502b corresponding to the scan-in pad signal 302, a waveform 502c corresponding to the scan-out data signal 404, and a waveform 502d corresponding to the functional response data signal 402.

Referring now to FIGS. 3-5, at time instant t₁, when a positive edge of the waveform 502a is received, the shift-in phase of the scan test is initiated. The scan test data obtained from the scan-in pad 302 begins to be transmitted to the scan register 304 in a shift-in phase of the scan test. Further, at time instant t₁, the waveform 502c including the expected data 408 is transmitted to the comparator 312. The waveform 502c is received from the scan-out pad 306. Additionally, at time instant t₁, the waveform 502d including functional response data signal 402 is transmitted out from the scan register 304 to the comparator 312. It should be realized by persons skilled in the art that the expected data signal 408 transmitted to the comparator 312 at time instant t₁ corresponds to the functional response data signal 402 transmitted out of the scan register 304, which in turn corresponds to the scan test data signal that was transmitted to the scan register 304 during a test clock signal cycle previous to the test clock signal cycle that begun at time instant t₁.

Thereafter, the scan test proceeds through various phases to convert the scan test data into functional response data which is obtained from the scan register 304 at time instant t₂.

Further, the functional response data FRES_0, corresponding to the scan test data prior to the test cycle at time instant t₁, is obtained from the scan register 304 at time instant t₁, is transmitted to the XOR gate 410. Additionally, the scan-out pad signal 404, depicted by the waveform 502c, received from the scan-out 306 is provided to the comparator 312 at time instance t₁, in which the scan-out pad signal 404 is transmitted to flip-flops 406a, 406b. Further, the test clock signal 424 is provided to the flip-flop 406a, 406b, and 406c. In an embodiment of the present invention, the flip-flops 406a, 406b, and 406c are D flip-flops. The flip-flop 406a is negative-edge triggered and flip-flops 406b and 406c are positive-edge triggered.

At time instant t₁, negative edge of the test clock signal 424, depicted by the waveform 502a, is received. Thus, the flip-flop 406a is triggered. As a result, the flip-flop 406a behaves as a transparent flip-flop and the scan-out pad signal 404 is transmitted by the flip-flop 406a as an output. Further, the flip-flop 406b, being positive edge triggered, blocks the scan-out pad signal 404. Therefore, the output signal of the flip-flop 406a becomes equal to the input scan-out pad signal 404 while the output signal value of the flip-flop 406b retains its value as it was during previous cycle. Since, the expected data (EXP_0, EXP_1) is transmitted only at the negative edges of the test clock signal 424, depicted by the waveform 502a; the flip-flop 406a transmits only when the scan-out pad signal 404 includes the expected data. Further, since the mask signal 412 is transmitted only at the positive edges of the test clock signal 424, the flip-flop 406b transmits only when it receives the mask signal. Thereafter, EXP_0 is transmitted to an input terminal of the XOR gate 410. The XOR gate 410 performs XOR operation on FRES_0 and EXP_0. The XOR gate 410 generates binary ‘1’ as the output when FRES_0 is not equal to EXP_0. Further, the XOR gate 410 generates binary ‘0’ as the output when FRES_0 is equal to EXP_0.

Thereafter, the output of the XOR gate 410 is transmitted to the AND gate 414. Since, the flip-flop 406b is not transmitting; the mask signal is binary ‘1’ for the negative edge test clock signal duration. As a result, subsequent to the AND logic operation, the output of the XOR logic (which is an input at the AND gate) is transmitted without being masked. In a scenario when the mask data signal 412 is low (during the positive edge duration of the test clock signal), the output of the XOR gate 410 is masked, subsequent to the AND logic operation by the AND gate 414. Further, since the output of the AND gate 414, subsequent to every test clock cycle, indicates whether the expected data is equal to the functional response data, the AND gate 414 output serves as a cycle-by cycle comparison signal. If the inputs to the XOR gate are different at any instant, the output of the XOR gate 410 becomes equal to binary ‘1’, and correspondingly the output of the AND gate 414 also becomes equal to binary ‘1’, thereby indicating that the functional response data is not equal to a desired response as indicated by the expected data.

Further, the output of the AND gate 414 is transmitted to the OR gate 418 as an input signal. The output of the OR gate 418 is connected input of the flip-flop 406c. Further, the output of the flip-flop 406c is provided as an input to the OR gate 418. Due to the above described circuit configuration, if the cycle-by-cycle comparison signal becomes high (binary ‘1’), i.e. a fault is detected during a scan test cycle; the output of the flip-flop 406c retains the high value through-out the scan test. It should be realized by persons skilled in the art that a scan test is composed of multiple scan test cycles, each of which lasts for one complete test clock signal cycle. Thus, the output of the flip-flop 406c serves as a pass/fail status signal which will indicate a pass status or a fail status of the IC tested using the system 300 subsequent to a complete scan test. Thus, if it is desirable to observe the fault detection status of the IC 300 after every scan test pattern cycle, cycle-by-cycle comparison signal provided by the AND gate 414 may be observed. Further, if it is desired to observe the pass/fail status of the IC 300 after the complete scan test, the output of flip-flop 406c is observed.

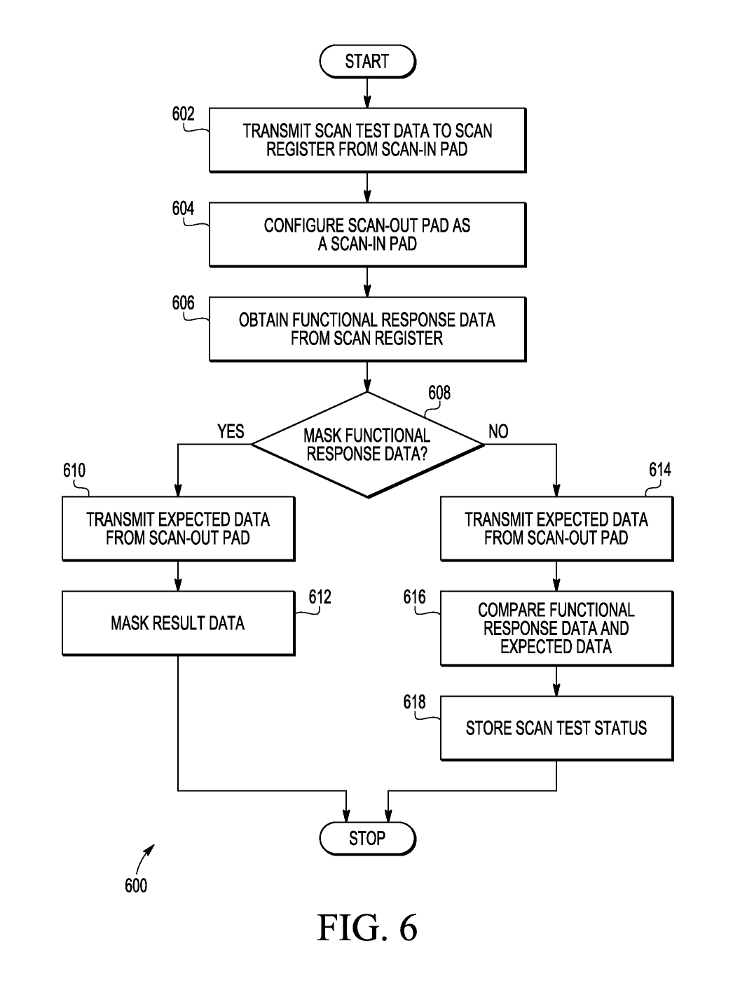

Referring to FIG. 6, a flowchart illustrating a method for scan testing an integrated circuit in accordance with an embodiment of present invention is shown. At a first step 602, the scan test data is transmitted from an external source, such as an ATPG, to the scan-in pad 302. The scan-in pad 302 then transmits the scan test data to the scan register 304, thereby loading the scan cells with the scan test data. Thereafter, the scan test data is applied to the internal logic of the IC 300. The scan cells capture the functional responses corresponding to the scan test data. Further, the functional response data is transmitted to the comparator 312. At step 604, the scan-out pad 306 is configured as a scan-in pad using the directional controller 308. In an embodiment the directional controller 308 uses tri state buffers to configure the scan-out pad 306 as a scan-in pad. The scan-out pad 306 transmits the expected data to the comparator 312. The expected data represents functional response of a flawless internal logic corresponding to the scan test data. The scan-out pad 306, also, transmits a mask signal. The mask signal prevents comparison of the functional response data with the expected data. The mask signal serves the purpose of signaling the comparator 312 to whether or not to compare the functional response data with expected data. The scan-out pad 306 transmits the expected data at the negative edge of the test clock signal and mask signal at the positive edge of the test clock signal.

At step 606, the functional response data is obtained from scan register 304. At step 608, a check is performed whether the functional response data is to be masked. If at step 608 it is determined that the functional response data needs to be masked then at step 610, the scan-out pad transmits the mask signal. The mask signal prevents the functional response data from being compared with the expected data. As a result, at step 612, the output of the comparator is held at its previous value, i.e., the functional response data of the scan register 304 is masked for the comparator. If at step 608 it is determined that the functional response data need not be masked then at step 614, the scan-out pad 306 transmits the expected data. The expected data is further transmitted to the comparator 312.

At step 616, the functional response data, received from the scan register, is compared with the expected data, received from the scan-out pad 306. The comparator 312 generates a pass/fail status signal depending on the comparison between the functional response data and the expected data to indicate the pass or fail status of the IC. The pass/fail status signal is generated when the scan test of IC is complete to indicate if the IC is functioning properly or not. In an embodiment the pass/fail signal is generated subsequent to each test pattern. In such a scenario the pass/fail status signal is know as a cycle by cycle debug signal.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

What is claimed is:

1. A system for testing an integrated circuit (IC), the IC including functional logic, the system comprising:
one or more scan registers, each having one or more scan cells for transmitting scan test data to the functional logic and for receiving functional response data from the functional logic;
one or more scan-in pads, connected to the one or more scan registers, wherein the one or more scan-in pads are configured to transmit the scan test data to the one or more scan registers at a positive edge and at a negative edge of a test clock signal;
one or more scan-out pads, connected to the one or more scan registers, wherein the one or more scan-out pads are configured to receive a mask signal and expected data based on the test clock signal; and
one or more comparators, connected between the one or more scan registers and the one or more scan-out pads, for comparing the expected data from the scan-out pads with the functional response data from the scan registers based on the mask signal and generating a scan test status signal.

2. The system of claim 1, further comprising one or more directional controllers connected to one or more data channels that connect the one or more scan cells with the one or more scan-out pads, and the one or more comparators with the one or more scan-out pads, wherein the one or more directional controllers direct a flow of the functional response data from the one or more scan cells to the one or more comparators and a flow of the expected data and the mask signal from the one or more scan-out pads to the one or more comparators.

3. The system of claim 2, wherein each comparator includes a flip-flop to hold the scan test status signal.

4. The system of claim 1, wherein the scan test data comprises scan test patterns generated by an Automatic Test Pattern Generator (ATPG).

5. The system of claim 1, wherein the one or more comparators operate in at least one of a monitor debug mode and a halt debug mode, wherein the monitor debug mode comprises generation of the scan test status signal subsequent to a scan test pattern cycle, and wherein the halt debug mode comprises generation of the scan test status signal subsequent to a scan test.

6. A method for testing an integrated circuit (IC), the IC comprising at least one scan-in pad, at least one scan-out pad, at least one scan register, at least one directional controller, and at least one comparator, the method comprising:
transmitting scan test data from the scan-in pad to the scan register at a positive edge and at a negative edge of a test clock signal, wherein the scan register transmits the scan test data to internal logic of the IC and captures functional response data corresponding to the scan test data from the internal logic;
configuring the scan-out pad to transmit a mask signal and expected data based on the test clock signal to the comparator; and
comparing the expected data from the scan-out pad and the functional response data from the scan register and generating a scan test status signal, wherein the expected data is compared with the functional response data based on the mask signal.

7. The method of claim 6, wherein the scan test data comprises scan test patterns generated by an Automatic Test Pattern Generator (ATPG).

8. The method of claim 6, wherein the comparator operates in at least one of a monitor debug mode and a halt debug mode, wherein the monitor debug mode comprises generation of the scan test status signal subsequent to a scan test pattern cycle, and the halt debug mode comprises generation of the scan test status signal subsequent to a scan test.
